(19) United States
(12) Patent Application Publication
(10) Pub. No.: US 2014/0259964 A1
(43) Pub. Date: Sep. 18, 2014

(54) Ventilating and Insulating Panels

(71) Applicant: Richard Frank Rickie, Ashford (GB)

(72) Inventor: Richard Frank Rickie, Ashford (GB)

(21) Appl. No.: 13/798,218

(22) Filed: Mar. 13, 2013

(51) Int. Cl. E04D 13/17; E04D 1/30; E04D 13/064; E04D 3/40; H01L 31/048

(52) U.S. Cl. CPC E04D 13/178; E04D 3/40; H01L 31/0483; E04D 13/064; E04D 1/30
USPC 52/1; 52/302.1; 52/173.3; 52/11

(57) ABSTRACT

The present invention provides an insulation panel used to form part of an exterior element of a buildings envelope for thermal insulation, ventilation, heating and cooling purpose having an internal duct that provides heat exchange between counter flowing waste and fresh air streams, oriented through the panel to minimise undesirable heat transfer. Ventilation air enters beneath the eaves, waste air exits beneath the ridge passing the coil of a reversible heat pump. The paired coil inside the building in the upper roof space within the fresh air stream is used for heating or cooling the building. Ducted waste air, leaving the building at this same position, can be supplied with a water mist before entering the heat exchanger to provide further indirect evaporative cooling of the incoming air stream. The waste air is also used to cool solar panels when fitted to the roof.

### CROSS-REFERENCE TO RELATED APPLICATIONS

Application Ser. No. 12/736,202 Applicant Richard Rickie Title Improvements in or relating to Insulating Panels

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### BACKGROUND OF THE INVENTION

Standards of insulation and airtightness requirements for building envelopes increase the significance of ventilation particularly within the buildings overall heating or cooling load. Mechanical ventilation with heat recovery (MVHR) can reduce this load. Factors affecting the efficiency of units include airflow configuration, the surface area the airflows are exposed to, even airflow distribution and pressure drop. Additional heating or cooling is required to compensate for fabric heat losses/gains when seasonal external temperatures dictate. To alleviate overheating MVHR's can be fitted with a summer bypass, this is only an interim solution (and not available for U.S. patent application Ser. No. 12/736,202 as the heat exchanger also forms the ducting that conveys ventilation air between the inside and outside of the building) as during hot weather conditions further cooling will be needed to maintain interior comfort. Solar photo voltaic (PV) can offset imported energy requirements but their efficiency is known to reduce with increasing temperature. Indirect evaporative coolers can be used to economically cool the incoming air without increasing its moisture content but become less effective as humidity levels rise. Reversible heat pumps can be used for both cooling and heating purpose by switching the roles of the evaporator and condenser coils although icing of the evaporator becomes a problem at times of more extreme temperatures.

1. Field of the Invention

The present invention relates to improvements in or relating to insulating panels. In particular, the present invention relates to an insulating panel used for ventilation with heat recovery as described in U.S. patent application Ser. No. 12/736,202 by the same inventor with the added facility for heating and cooling the internal space of buildings and with the capability for cooling photovoltaic panels.

2. Description of Related Art

U.S. patent application Ser. No. 12/736,202 Applicant Richard Rickie Title Improvements in or relating to Insulating Panels the disclosures of which are incorporated herein by reference.

US 20090236074 Composite Insulating Panel Gregory Flynn et al describe an insulating panel for use in a roof wall or floor having facility for heat recovery via air or water conduit within the panel used to recover solar heat from the panels exterior to be used for heating purpose when conduits are situated adjacent an outer profiled sheet and used to recover heat risen from within the building from the panels interior sheet so to cool the space below when conduits are situated adjacent the inner sheet of the panel. This panel is designed to remove a build up of heat from either of its facing sheets. During times of cold overcast skies the panel's conduits will make no contribution to the heating requirement of the building and an alternative heat source will be needed for fabric, infiltration and ventilation losses. During the hottest ambient conditions the panel will recover more heat than may be useable from both conduit circuits when heat gains will be a problem and the building will require auxiliary cooling to maintain comfort.

In US 2006/0191278 A1 titled Evaporative Coolers the inventor Roger Cooke describes an evaporative cooler in a housing mounted within the roof space of a pitched roof with the housing inlet, which mounts evaporative cooling pads, lying at or adjacent to the plane of the roof. The evaporation takes place in pads fed by water from a spray or drip supplied by pumped water from a reservoir with overflow, allowing rain water run off. Fresh cooled air after being drawn through the pads by fan and transported by appropriate ducting.

Evaporative coolers, particularly roof mounted models that add a concentrated weight burden to the roof, are unsightly the aforementioned invention goes some way to remedy this although an indirect misting system could be more discreet.

US20110308265 Seng K. Phannavong describes An Integrated Ventilation Unit configured to provide ventilation and conditioned air to an inside space may include a heat pump system, an energy recovery device and a control unit. The heat pump system may include a first coil located at a supply air side of the ventilation unit, a second coil located at an exhaust air side of the ventilation unit, and a compressor. The energy recovery device may be configured to transfer heat between a return air stream and a supply air stream and the control unit may be configured to control operation of the heat pump system and the energy recovery device. Whilst this may optimise the control of standard HVAC equipment the ventilation unit will require careful sizing and complex controls and ductwork in order to satisfy the requirements of individual areas of building also unless sited at an exterior wall will require insulated ductwork.

A plurality of standard sized smaller units that only require small bore ductwork would discreetly serve individual areas and permit simpler control to be used.

Accordingly, it is desirable to provide a ventilating and insulating panel system that provides an efficient means for insulating, heating and cooling a building.

Whole house heat exchangers (counterflow being the most efficient of these) can be combined with heat pumps and connected to a system of ducts for this purpose but, as their efficiency relies mostly on the surface area available for heat exchange, they become either more bulky with higher efficiency and/or require greater fan power to overcome resistance to flow. By including heat recovery means within an exterior element of a building a greater surface area for heat exchange becomes available without imposing on the internal space, also there are many advantages in having small scale individual heating and cooling systems that serve individual internal spaces. For example differing room temperatures/air change requirement can be maintained more economically, less ductwork is needed where panels are adjacent to rooms needing to be vented, isolated systems will reduce noise transmission from one room to another.

### BRIEF SUMMARY OF THE INVENTION

The present invention provides an insulation panel used to form part of an exterior element of a buildings envelope for thermal insulation, ventilation, heating and cooling purpose having an internal duct, divided longitudinally into at least two channels used for conveying opposing waste and fresh air streams, running diagonally through a depth of the panel, so that when used as a roofing panel the channels open internally proximal to a ridge and externally at the eaves with waste air directed to the underside of the roof covering.

The panels provide a high surface area available for heat exchange (most of the building envelope available), low restriction to airflow (channels of heat exchanger are straight and relatively large), no ductwork insulation is required, an earlier weather tight building can be erected (sandwich panels would provide several operations at once). The panels are ideally suited for integration with other energy/resource saving technologies including, a photo voltaic array with cooling, a reversible heat pump with coils discreetly sited within the inside and outside of the roofs ridge to provide heating or cooling via the ventilation air, an indirect evaporative cooler using a water spray/mist (ideally using harvested rainwater) to the extract air whilst inside the building, with excess water running to the gutter (from where it could be recycled), to provide efficient cooling of the incoming fresh air. By careful arrangement the integration of these technologies provides a flexible, compact, discreet and efficient ventilation and insulation system.

### BRIEF DESCRIPTION OF THE SEVERAL VIEWS OF THE DRAWINGS

U.S. patent application Ser. No. 12/736,202 Applicant Richard Rickie Title Improvements in or relating to Insulating Panels the disclosures of which are incorporated herein by reference.

FIG. 1a is a sectional view of the manifolds at the upper end of the panel

FIG. 2a is a sectional view of the lower end of the panel

FIG. 3a is a sectional view of the panel at the ridge showing fan upstream of coil for hot climates.

### DETAILED DESCRIPTION OF THE INVENTION

An insulated panel having a thermally insulated core with load carrying facings on opposed surfaces of the core and a strengthening frame at the edges of the core used for a buildings sloping roof, containing an air duct having two adjacent channels, a fresh air channel and a waste air channel, separated by a conductive membrane for the purpose of heat transmission between induced airflows within the two channels, running diagonally through the thermal insulation of the panel from the upper end of the panel inside of the building to the lower end at the eaves, with the waste air channel directed to a continuous air gap, between the outer load carrying facing and the underside of a supported outer weatherproof covering, ducting the waste air from the eaves to the ridge 52, and exiting externally at the ridge and with the fresh air channel ducted to admit fresh air from beneath the eaves used for ventilating the enclosed space within the building.

Optionally, the panel's weatherproof covering contains photovoltaic cells.

Preferably, the fresh air channel and waste air channel are subdivided by webs forming a plurality of continuous internal channels terminating in fresh air and waste air manifolds.

Suitably, each manifold is connectable to further ductwork, the ducts to the upper end of the panel being in fluid connection with the buildings internal environment and the ducts to the lower end of the panel being in fluid communication with the buildings external environment, said ducts having facility for filtration 24 of the air before admission into the air channels.

Optionally, the fresh air duct is fitted with an indoor finned coil 30, positioned in the fresh air flow proximate to where the said air flow leaves the fresh air channel internally beneath the ridge, in cyclic fluid communication, via a compressor and expansion and reversing valves, with an outdoor finned coil 31 positioned in the waste air flow duct proximate the ridge externally.

Optionally, the waste air flow duct is fitted with a fan 40 proximate the ridge externally to discharge air from the continuous air gap beneath the ridge.

Optionally, the waste air duct is fitted with a nozzle (or nozzles) positioned in the waste air flow close to the upper end of the waste air channel and a nozzle positioned in the continuous air gap beneath the weatherproof covering used to emit a fine spray of water into the waste air flow.

Preferably, the lower end of the waste air flow duct is in restricted communication, via a shutter, with the buildings rainwater gutter for excess water and condensate run off.

Optionally, the water spray can use stored harvested rain water and recycle water from the gutter.

Suitably, intake and extract fans and back draught shutters (not shown) positioned in the fresh and waste air ducts promote desired air flows within the ductwork system terminating at registers located strategically throughout the building.

Suitably, the system has heating, ventilation and air conditioning controlled by one or more switches and sensors.

Optionally, the panels can be adapted for use in a wall of a building.

The above and other aspects of the invention will now be illustrated in further detail, by way of example only, with reference to the accompanying drawings and including drawings of improvements in or relating to insulation panels by same inventor. Heat exchanger should be understood to refer to the channels within the insulated core of the panel. In preferred embodiments, the panels load carrying facings 21 are constructed of oriented strand board (optionally recycled plastic sheets) with the foam core 20, preferably rigid polyisocyanurate (PIR), containing a polycarbonate heat exchanger (depicted by 12a, 14 and 12b), supported by purlins, of a structural insulated panel (SIP) building form a sloping roof, contains an air duct having two adjacent channels, a fresh air channel 12a and a waste air channel 12b, separated by a conductive membrane 14, these channels being subdivided by webs to augment heat transmission between the fresh air and waste air flows and reinforce the structure, so forming a linear counter flow heat exchanger that runs diagonally through the thermal insulation of the panel, orchestrated to ensure heat transmission is restricted to that between the airflows. The heat exchanger is orientated from the upper end of the panel inside of the building to the lower end at the eaves 50 and terminates with the subdivided channel ends suitably adapted for connection to manifolds, thus also ducting the air flows between the inside and outside of the building. From the lower end of heat exchanger the waste air is directed to a continuous air gap 22, by use of a shutter 34 (gravity closing for simplicity) restricting air flow back to the gutter 51 while permitting condensate or residual spray water run off. The air gap is maintained between the load carrying waterproof surface of the insulation and the underside of the outer weatherproof covering 23 (by counter battens or mounting spacers used for an optional photo voltaic array) to run continuously up to be expelled externally beneath a raised ridge 52 capping with mesh screen. The lower fresh air manifold connects to a filter housing 24 with mesh screen fitted in the soffit and accessible beneath the eaves 50, for ease of maintenance, providing clean fresh air intake.

Mechanical intake 15a and extract 15b fans are situated at the upper end of the heat exchangers fresh and waste air manifolds (in the vicinity of the apex of the roof space where a collar tie could be used for support) to induce counter flowing air flows between their corresponding small bore ducts 13a & 13b providing balanced ventilation ducted to and from pertinent locations within the building. Suitably the waste air ductwork also houses a filter upstream of the heat exchanger to control fouling. Preferably the ductwork also houses the condenser/evaporator finned coil 30 of a reversible heat pump situated in the fresh air flow downstream of the heat exchanger proximate beneath the ridge inside the roof space of the building (also supported above a collar tie for ease of concealment whilst remaining accessible for maintenance), the matching evaporator/condenser finned coil 31 being situated externally at the ridge, accessible for maintenance beneath raised ridge capping (preferably through access from inside the roof space), in the path of the expelled waste air flow to provide further heating or cooling of the fresh air flow following heat exchange.

In preferred embodiments, the waste airflow is sprayed with a water mist emitted from a nozzle(s) 32 located upstream of the heat exchanger to provide indirect evaporative cooling to the incoming fresh air flow, excess water will discharge to the gutter 51.

Optionally a fan 40 is positioned externally at the ridge, accessible for maintenance beneath raised ridge capping, drawing an ambient air supply along the continuous air gap 22 beneath weatherproof covering 23 from the eaves by use of a gravity shutter 34, positioned at the lower end of the air gap near the gutter, used to limit waste air leakage to this area whilst permitting water run off. The ambient air will be drawn to the ridge having combined with the waste air, that will be close to ambient temperature after passing through the heat exchanger, providing supplementary cooling for the external heat pump coil 31 and/or the photo voltaic cells during times of excessive heat build up.

For use where extreme cooling demand is required a water spray/mist can be emitted by a nozzle(s) 33 located in the air gap beneath the weatherproof covering 23 to provide additional cooling of the heat pump coil and/or the photo voltaic cells, with excess water discharging to the gutter from where it could be recycled.

When fitted with sensors and controls the panels provide a plurality of multiple ‘closed ventilation systems’ that through small bore ductwork will discretely and economically supply fresh air conditioned to the requirements of selected individual areas within a building.

The described system offers significant advantages in terms of improvement of air quality over conventional air conditioning systems in which most of the air passing through the system is recycled with perhaps only around 20% of the air being exchanged for fresh air in order to reduce the cooling load. A system according to the present invention supplies 100% fresh air for ventilation while in cooling mode with a minimal energy use due to the exchange of air. The system also leads to a reduction in the build-up of condensation within a building.

The emphasis of the systems use has been described for a hotter climate, alternatives for use in a colder climate, particularly with regard to icing and the problem of ice dams, are that the external heat pump coil should be downstream of the external fan allowing melt ice, during a defrost cycle, to run to the outer weatherproof covering. During severe cold weather an auxiliary form of heating would be necessary, in an adapted system a small furnace positioned in the waste air ductwork upstream of the heat exchanger permitting excess heat, that not recovered by the heat exchanger channels, to alleviate icing problems and aid evaporation at the ridge coil, increasing overall heat recovery of the system.

1. An insulated panel having a thermally insulating core with load carrying facings on opposed surfaces of the core and a strengthening frame at the edges of the core used for a buildings sloping roof, containing an air duct having two adjacent channels, a waste air channel and a fresh air channel, separated by a conductive membrane for the purpose of heat transmission between induced airflows within the two channels, running diagonally through the thermal insulation of the panel from the upper end of the panel inside of the building to the lower end at the eaves, with the waste air channel directed to a continuous air gap, between the outer load carrying facing and the underside of a supported outer weatherproof covering, ducting the waste air from the eaves to the ridge, and exiting externally at the ridge and with the fresh air channel ducted to admit fresh air from beneath the eaves used for ventilating the enclosed space within the building.

2. The panel as claimed in 1 wherein the weatherproof covering contains photovoltaic cells.

3. The panel as claimed in 2 wherein the fresh air channel and waste air channel are subdivided by webs forming a plurality of continuous internal channels terminating in fresh air and waste air manifolds.

4. The panel as claimed in 3 wherein each manifold is connectable to further ductwork, the ducts to the upper end of the panel being in fluid connection with the buildings internal environment and the ducts to the lower end of the panel being in fluid communication with the buildings external environment, said ducts having facility for filtration of the air before admission into the air channels.

5. The panel system as claimed in 4 with an indoor fumed coil, positioned in the fresh air flow duct proximate to where the said air flow leaves the fresh air channel internally beneath the ridge, in cyclic fluid communication, via a compressor and expansion and reversing valves, with an outdoor finned coil positioned in the waste air flow duct proximate the ridge externally.

6. The panel system as claimed in 5 with a nozzle positioned in the duct containing waste air close to the upper end of the waste air channel and a nozzle positioned in the waste air duct adjacent to the outdoor coil used to emit a fine spray of water into the waste air flow.

7. The panel system as claimed where the lower end of the waste air flow duct is in restricted communication, via a shutter, with the buildings rainwater gutter for excess water and condensate run off.

8. The panel system as claimed where the water spray can use stored harvested rain water and recycle water from the gutter.

9. The panel system as claimed with extract and intake fans and back draught shutters positioned in the waste and fresh air ducts terminating at registers located strategically within the building.

10. An insulating panel system as claimed and having heating, ventilation and air conditioning controlled by one or more switches and sensors.

11. The use of a panel described for an exterior element of a building.
